(19) United States
(12) Patent Application Publication
(10) Pub. No.: US 2005/0276018 A1
(43) Pub. Date: Dec. 15, 2005

(54) Thermal management system for a portable computing device

(76) Inventors: Earl W. Moore, Cypress, TX (US); Mark S. Tracy, Tomball, TX (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 10/867,526

(22) Filed: Jun. 14, 2004

(51) Int. Cl. H05K 7/20

(52) U.S. Cl. 361/695

(57) ABSTRACT

A thermal management system for a portable computing device comprises at least one vent formed in a housing of the portable computing device and a thermal module adapted to dissipate thermal energy from within an interior area of the housing via the at least one vent. The system also comprises a sealing member adapted to prevent moisture from migrating from the at least one vent to the interior area of the housing.

### BACKGROUND

Portable computing devices, such as laptop or notebook computers, tablet personal computers, and other types of portable electronic computing devices, generally include vents to enable dissipation of thermal energy generated by electronic components of the portable computing device. However, such vents also expose the electronic components of the portable computing device to moisture, especially if the portable computing device is used in or otherwise exposed to a high humidity environment. Alternatively, the portable computing device may be configured without vents. However, a ventless housing or chassis generally limits the performance and/or power capabilities of the portable computing device because generally lower power and/or lower performance electronic components which generate less thermal energy must be used.

### SUMMARY OF THE INVENTION

In accordance with one embodiment of the present invention, a thermal management system for a portable computing device comprises at least one vent formed in a housing of the portable computing device and a thermal module adapted to dissipate thermal energy from within an interior area of the housing via the at least one vent. The system also comprises a sealing member adapted to prevent moisture from migrating from the at least one vent to the interior area of the housing.

### BRIEF DESCRIPTION OF THE DRAWINGS

For a more complete understanding of the present invention and the advantages thereof, reference is now made to the following descriptions taken in connection with the accompanying drawings in which:

FIG. 1 is a diagram illustrating an embodiment of a portable computing device in which a thermal management system in accordance with the present invention is incorporated;

FIG. 2 is an exploded assembly diagram illustrating an embodiment of a thermal management system for a portable computing device in accordance with the present invention;

FIG. 3 is a diagram illustrating a bottom view of the thermal management system illustrated in FIGS. 1 and 2; and

FIG. 4 is a diagram illustrating another embodiment of a thermal management system for a portable computing device in accordance with the present invention.

### DETAILED DESCRIPTION OF THE DRAWINGS

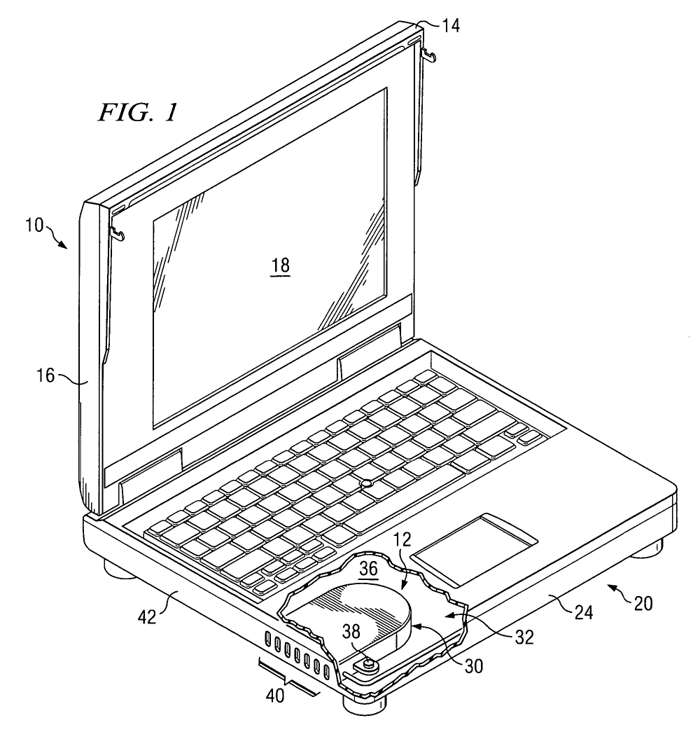

The preferred embodiments of the present invention and the advantages thereof are best understood by referring to FIGS. 1-4 of the drawings, like numerals being used for like and corresponding parts of the various drawings.

FIG. 1 is a diagram illustrating an embodiment of a portable computing device 10 in which a thermal management system 12 in accordance with the present invention is incorporated. In the embodiment illustrated in FIG. 1, portable computing device 10 comprises a laptop or notebook computer 14 having a display member 16 with a display device 18 rotatably coupled to a base member 20. However, it should be understood that thermal management system 12 may be used with or otherwise incorporated into other types of portable computing devices. Thermal management system 12 enables cooling or dissipation of thermal energy generated by components of portable computing device 10 while substantially preventing or eliminating moisture exposure to internal electronic components of portable computing device 10.

In the embodiment illustrated in FIG. 1, thermal management system 12 comprises a thermal module 30 disposed within a housing 24 of base member 20 and adapted to dissipate thermal energy from within an interior area 32 of housing 24 of portable computing device 10. However, it should be understood that thermal management system 12 may be disposed or otherwise incorporated at other locations of portable computing device 10. In the embodiment illustrated in FIG. 1, thermal module 30 is coupled to a floor 36 of housing 24 using fasteners 38. However, it should be understood that thermal module 30 may be coupled to different locations of portable computing device 10 using a variety of different types of fastening devices. In the embodiment illustrated in FIG. 1, thermal module 30 dissipates thermal energy from within interior area 32 via an exhaust vent 40 formed in a wall 42 of housing 24. For example, as illustrated in FIG. 1, thermal module 30 is disposed within base member 20 adjacent exhaust vent 40 such that thermal module 30 dissipates thermal energy from within interior area 32 via exhaust vent 40.

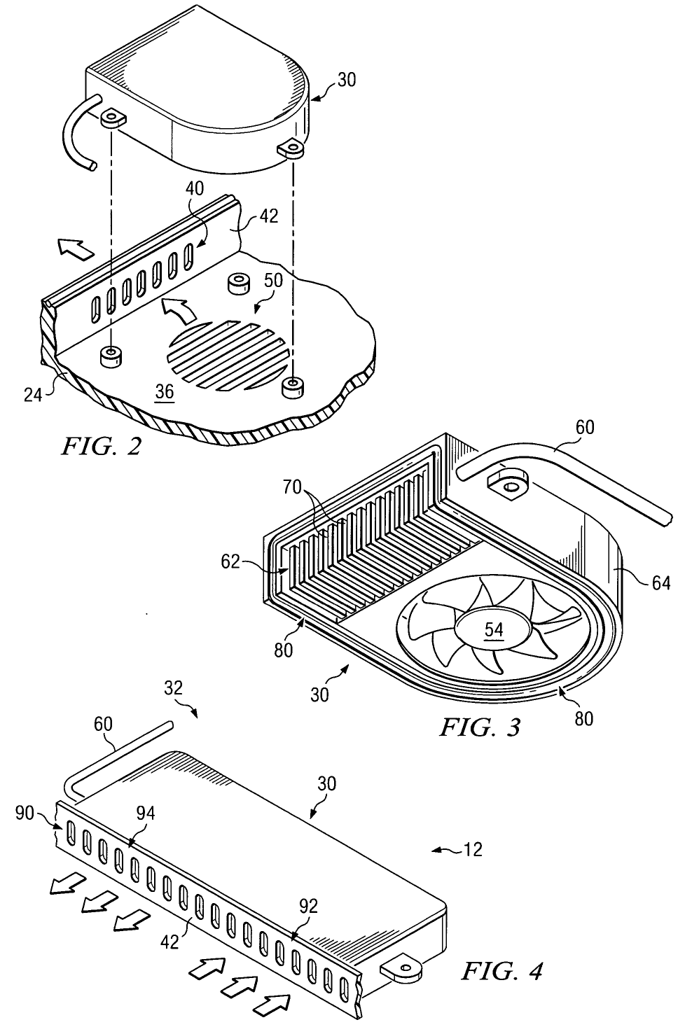

FIG. 2 is an exploded assembly diagram illustrating thermal management system 12 in accordance with an embodiment of the present invention, and FIG. 3 is a diagram illustrating a bottom view of thermal module 30 in accordance with an embodiment of the present invention. In the embodiment illustrated in FIG. 2, an intake vent 50 is disposed in floor 36 of housing 24 corresponding to a location of thermal module 30. In operation, thermal module 30 generates an air flow through housing 24 from intake vent 50 to exhaust vent 40 to dissipate thermal energy from within interior area 32 of housing 24. For example, as illustrated in FIG. 3, thermal module 30 comprises a fan 54 for generating an air flow through housing 24 from intake vent 50 to exhaust vent 40 for dissipating thermal energy from within interior area 32 of housing 24. In some embodiments, thermal module 30 comprises a water-resistant fan 54 to accommodate generally high humidity environments or other types of applications.

In the embodiment illustrated in FIGS. 2 and 3, thermal module 30 also comprises a heat pipe 60 and a heat exchanger 62. Heat pipe 60 is coupled to heat exchanger 62 within a housing 64 of thermal module 30 and extends from heat exchanger 62 to a desired or predetermined location within interior area 32 of housing 24. In operation, heat pipe 60 transfers thermal energy from within interior area 32 of housing 24 to heat exchanger 62 to enable dissipation of thermal energy from within interior area 32 via the air flow generated by fan 54 from intake vent 50 to exhaust vent 40. For example, as illustrated in FIGS. 2 and 3, heat exchanger 62 comprises a plurality of fins 70 disposed proximate to or adjacent exhaust vent 40 such that air flow generated by fan 54 is drawn into intake vent 50 and passes over and/or through fins 70 to exhaust vent 40 to dissipate thermal energy transferred from heat pipe 60 to heat exchanger 62 from interior area 32 of housing 24.

Thermal management system 12 also comprises a sealing member 80 for preventing moisture which may otherwise enter intake vent 50 and/or exhaust vent 40 from migrating to interior area 32 of housing 24. For example, in the embodiment illustrated in FIG. 3, sealing member 80 comprises a flexible gasket or O-ring-type member 82 disposed about a periphery of thermal module 30 to prevent moisture from migrating beyond thermal module 30. Sealing member 80 may be formed as an integral component of thermal module 30, for example, as illustrated in FIG. 3. However, it should be understood that sealing member 80 may also comprise a discrete or separate element of system 12. In some embodiments, sealing member 80 comprises a flexible rubber-type material to form a moisture-proof seal between intake vent 50 and/or exhaust vent 40 and interior area 32 of housing 24. However, it should be understood that sealing member 80 may also be constructed from other materials.

Thus, in the embodiment illustrated in FIGS. 2 and 3, sealing member 80 is disposed between intake vent 50 and/or exhaust vent 40 and interior area 32 of housing 24 to prevent moisture from entering interior area 32 which may otherwise enter housing 24 via intake vent 50 and/or exhaust vent 40. In the embodiment illustrated in FIGS. 2 and 3, sealing member 80 is disposed about a periphery of thermal module 30, thereby positioning sealing member 80 about a periphery of both intake vent 50 and exhaust vent 40. However, it should be understood that sealing member 80 may be otherwise positioned between interior area 32 and intake vent 50 and exhaust vent 40. Further, in the embodiment illustrated in FIGS. 2 and 3, sealing member 80 comprises a single sealing element having at least a portion thereof disposed between both intake vent 50 and exhaust vent 40 and interior area 32. However, it should be understood that sealing member 80 may also be formed from multiple sealing elements such that each disposed between interior area 32 and intake vent 50 and/or exhaust vent 40, thereby preventing moisture which may otherwise enter intake vent 50 and/or exhaust vent 40 from entering interior area 32 of housing 24.

FIG. 4 is a diagram illustrating another embodiment of thermal management system 12 in accordance with the present invention. In the embodiment illustrated in FIG. 4, thermal module 30 is disposed adjacent a vent 90 formed in wall 42 of portable computing device 10 such that thermal module 30 dissipates thermal energy from within interior area 32 via vent 90. For example, in the embodiment illustrated in FIG. 4, heat pipe 60 extends to a desired or predetermined location within interior area 32 of portable computing device 10 to transfer thermal energy from within portable computing device 10 towards vent 90. In operation, thermal module 30 is configured to draw an airflow into a portion 92 of vent 90 and exhaust the airflow through a portion 94 of vent 90 to dissipate thermal energy transferred from within interior area 32 by heat pipe 60.

Thus, embodiments of the present invention provide thermal management of a portable computing device via venting and/or airflow cooling while substantially preventing or eliminating moisture exposure to internal electronic components of the portable computing device, thereby enabling additional types of electronic components to be used in the portable computing device such as high performance or high power processors and effectively isolating the internal electronics from exposure to moisture. Further, embodiments of the present invention enable use of the portable computing device in additional environments or applications, such as high humidity environments or other types of environments or applications where moisture is a factor or concern.

1. A thermal management system for a portable computing device, comprising:
at least one vent formed in a housing of the portable computing device;
a thermal module adapted to dissipate thermal energy from within an interior area of the housing via the at least one vent; and
a sealing member adapted to prevent moisture from migrating from the at least one vent to the interior area of the housing.

2. The system of claim 1, wherein the thermal module comprises a fan.

3. The system of claim 1, wherein the sealing member comprises an integral component of the thermal module.

4. The system of claim 1, wherein the thermal module comprises a heat exchanger disposed proximate to the at least one vent.

5. The system of claim 1, wherein the thermal module comprises a heat pipe adapted to transfer the thermal energy within the interior area of the housing toward the at least one vent.

6. The system of claim 1, wherein the thermal module comprises a heat pipe extending from a heat exchanger disposed proximate to the at least one vent to the interior area of the housing.

7. The system of claim 1, wherein the sealing member is disposed about a periphery of the thermal module.

8. The system of claim 1, wherein the sealing member is disposed between the at least one vent and the interior area of the housing.

9. The system of claim 1, wherein the thermal module comprises a water-resistant fan.

10. The system of claim 1, wherein the at least one vent comprises an intake vent and an exhaust vent.

11. The system of claim 10, the thermal module adapted to generate an airflow from the intake vent to the exhaust vent.

12. The system of claim 10, at least a portion of the sealing member disposed between the interior area of the housing and both the intake vent and the exhaust vent.

13. A thermal management system for a portable computing device, comprising:
a vent formed in a housing of the portable computing device; and
a thermal module adapted to dissipate thermal energy from with an interior area of the portable computing device via the vent, the thermal module adapted to prevent moisture from migrating from the vent to the interior area of the portable computing device.

14. The system of claim 13, wherein the thermal module comprises a sealing member disposed between the vent and the interior area of the portable computing device.

15. The system of claim 13, wherein the thermal module comprises a heat pipe adapted to transfer thermal energy from within the interior area of the portable computing device toward the vent.

16. The system of claim 13, wherein the thermal module comprises a heat exchanger disposed proximate to the vent.

17. The system of claim 13, wherein the thermal module comprises a heat pipe extending from a heat exchanger into the interior area of the portable computing device.

18. The system of claim 13, wherein the thermal module comprises a sealing member disposed about a periphery thereof.

19. A thermal management system for a portable computing device, comprising:
means for dissipating thermal energy from within an interior area of the portable computing device via a vent of the portable computing device; and
means for preventing moisture from migrating from the vent to the interior area of the portable computing device.

20. The system of claim 19, wherein the means for dissipating comprises means for transferring the thermal energy from the interior area of the portable computing device to the vent.

21. The system of claim 19, wherein the means for preventing comprises sealing means disposed between the vent and the interior area of the portable computing device.

22. The system of claim 19, wherein the means for preventing is disposed about a periphery of the means for dissipating the thermal energy.

23. The system of claim 19, wherein the means for dissipating comprises means for generating an airflow through the vent to dissipate the thermal energy.
